(19) United States
(12) Patent Application Publication
(10) Pub. No.: US 2025/0149416 A1
(43) Pub. Date: May 8, 2025

(54) SEMICONDUCTOR ASSEMBLIES WITH WIRE-BONDED TRACES, AND METHODS FOR MAKING THE SAME

(71) Applicant: Micron Technology, Inc., Boise, ID (US)

(72) Inventors: Faxing Che, Singapore (SG); Amirul Afiq Bin Hud, Singapore (SG); Darren Tan Hong Suang, Singapore (SG); Hong Wang Ng, Singapore (SG); Soon Sing Ng, Singapore (SG); Chin Hui Chong, Singapore (SG)

(21) Appl. No.: 18/920,479

(22) Filed: Oct. 18, 2024

Related U.S. Application Data
(63) Continuation of application No. 63/547,045, filed on Nov. 2, 2023.

(51) Int. Cl. H01L 23/498; H01L 21/48; H01L 21/66; H01L 23/00; H01L 23/552; H01L 25/00; H01L 25/065

(52) U.S. Cl. CPC H01L 23/49811; H01L 21/4853; H01L 22/32; H01L 23/49827; H01L 23/49838; H01L 23/552; H01L 24/48; H01L 25/0652; H01L 25/50; H01L 2224/48229; H01L 2924/15165

(57) ABSTRACT

A semiconductor device assembly is provided. The assembly includes a substrate and a semiconductor device. The substrate includes a first conductive layer, the first conductive layer having a first trace with a first exposed pad and a second trace with a second exposed pad. A wire bond runs above the first conductive layer to connect the first exposed pad to the second exposed pad, such that the first trace and the second trace are only connected via the wire bond. The semiconductor device includes an electrical connection to the first trace.

### CROSS-REFERENCE TO RELATED APPLICATION(S)

The present application claims priority to U.S. Provisional Patent Application No. 63/547,045, filed Nov. 2, 2023, the disclosure of which is incorporated herein by reference in its entirety.

### TECHNICAL FIELD

The present disclosure generally relates to semiconductor device assemblies, and more particularly relates to semiconductor assemblies with wire-bonded traces, and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1A is a simplified cross-sectional view of an example semiconductor device assembly.

FIG. 1B is a simplified plan view of an example first conductive layer.

FIG. 2A is a simplified cross-sectional view of an example semiconductor device assembly with wire-bonded traces.

FIG. 2B is a simplified plan view of an example first conductive layer with wire-bonded traces.

FIGS. 3A-3D is a simplified plan view of an example semiconductor assembly with wire-bonded traces.

FIG. 4 is a simplified cross-sectional view of an example substrate with wire-bonded traces.

FIG. 5 is a schematic view showing a system that includes a semiconductor device assembly configured in accordance with an embodiment of the present technology.

FIG. 6 is a flow chart illustrating a method of making a semiconductor device assembly in accordance with an embodiment of the present technology.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc.

One approach used to meet this goal is semiconductor device assemblies with multi-layer substrates. These substrates include layers of conductive material, each layer having traces that can be connected by vias to route signals or power between different areas of the board. A trace is a thin conductive line that carries signals or power, and a via is a small hole which enables a vertical connection between traces on different layers, running down through a multi-layer substrate.

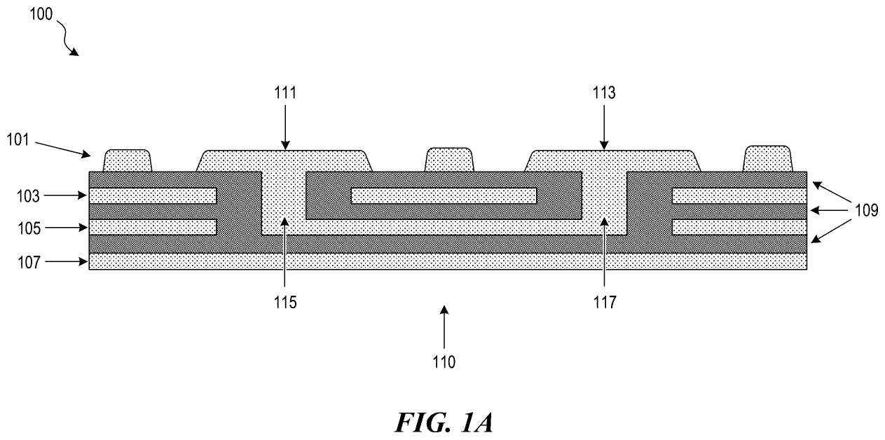

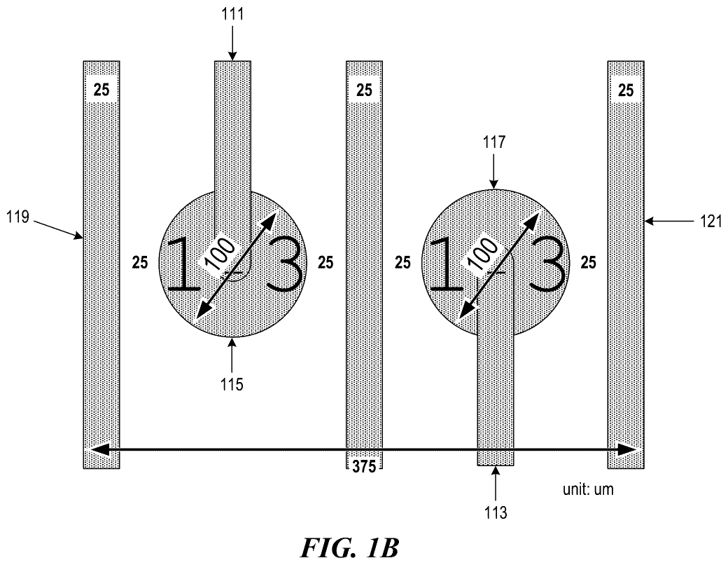

In FIG. 1A, a simplified cross-sectional view of an example semiconductor device assembly 100 is illustrated. The assembly 100 includes a substrate 110 with a first conductive layer 101, a second conductive layer 103, a third conductive layer 105, and a fourth conductive layer 107. A dielectric layer 109 is disposed between the conductive layers. In order to connect a first trace 111 to a second trace 113 that is adjacent to the first trace 111 on the first conductive layer 101, a first via 115 and a second via 117 must run down through the substrate 110 to connect on the third conductive layer 105. One disadvantage with this design, as illustrated in FIG. 1A, is that this requires a greater amount of conductive material in order to bridge what is a relatively short gap between the traces on the first conductive layer 101. However, another disadvantage with this design is that it also increases the potential for electromagnetic “crosstalk” between conductive layers in the substrate 110. That is, the signals being conducted by one layer may interfere or affect the signals being sent by an adjacent conductive layer, even if there is a layer of dielectric material 109 disposed between them. The potential for crosstalk is increased due to the design of the vias 115 and 117, which break up the second conductive layer 103 and third conductive layer 105, and can compromise the dielectric shielding 109 between layers.

Another disadvantage with this design is the space the first via 115 and the second via 117 occupy on the first conductive layer 101. In FIG. 1B, a simplified plan view of an example first conductive layer 101 is illustrated. The diameter of the first via 115 and second via 117 on the first conductive layer 101 is shown to be 100 μm (micrometers). Due to the constraints of this design, adding a third trace 119 and a fourth trace 121 occupies 375 μm, which is a larger space due to the presence of the first via 115 and second via 117.

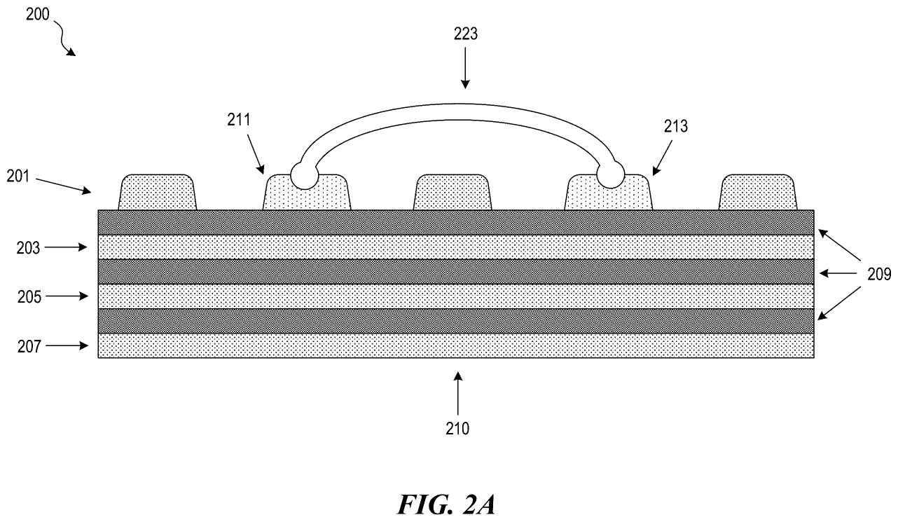

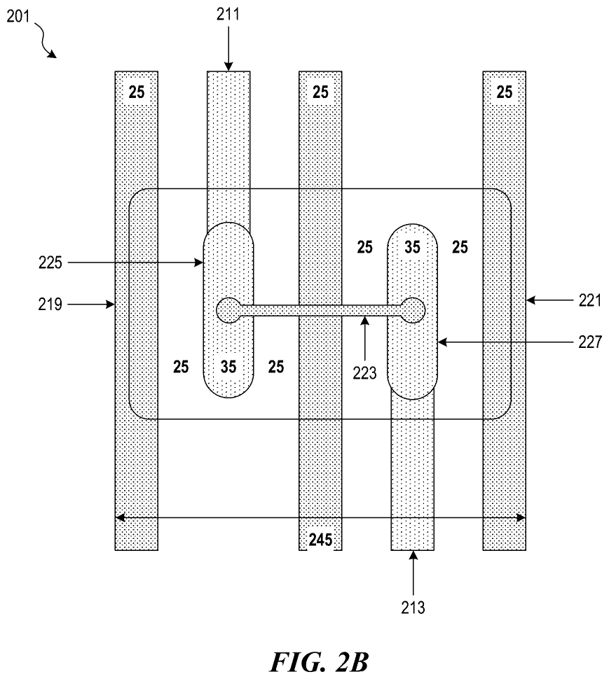

Embodiments of the present disclosure solve these problems and others by providing wire-bonded traces, and methods for making the same. FIG. 2A is a simplified cross-sectional view of an example semiconductor device assembly 200 with wire-bonded traces. The assembly 200 can include a substrate 210, the substrate 210 including a first conductive layer 201. The first conductive layer 201 can have a first trace 211 with a first exposed pad and a second trace 213 with a second exposed pad. A wire bond 223 can run above the first conductive layer 201 to connect the first exposed pad to the second exposed pad, such that the first trace 211 and the second trace 213 are only connected via the wire bond 223. The first trace 211 and the second trace 213 can be horizontally aligned on the first conductive layer 201, as illustrated. In alternative embodiments, the first trace 211 and the second trace 213 may occupy disparate heights, while being disposed on an equivalent conductive layer. Also included in the assembly 200 is a semiconductor device, which will be illustrated in later figures, the semiconductor device including an electrical connection to the first trace 211. The substrate 210 can be a multi-layer substrate, as illustrated. The substrate 201 can include a second conductive layer 203, a third conductive layer 205, and a fourth conductive layer 207. A dielectric layer 209 can be disposed between the conductive layers. In contrast to the first via 115 and second via 117 from FIG. 1, the wire bond 223 can connect the first trace 211 to the second trace 213 not by running down and dividing the second conductive layer 203 and the third conductive layer 205, but by running over the first conductive layer 201. An advantage of this design is the reduced likelihood of crosstalk between the conductive layers. In additional embodiments, in which the second conductive layer 203 is disposed below the first conductive layer 201 with an unbroken sheaf of dielectric material 209 disposed between the first conductive layer 201 and the second conductive layer 203, the second conductive layer 203 can comprise an unbroken conductive layer. This unbroken conductive layer can be configured for routing power and for blocking electromagnetic crosstalk from reaching the first conductive layer 201. In other embodiments, a dielectric layer can cover the first conductive layer 201. In such embodiments, the dielectric layer can include openings to allow the wire bond 223 to connect to the first exposed pad and the second exposed pad of the first trace 211 and the second trace 213.

An additional benefit of this design is the reduced spacing it allows between traces. FIG. 2B is a simplified plan view of an example first conductive layer with wire-bonded traces. The assembly 200 can include a substrate, the substrate including a first conductive layer 201. The first conductive layer 201 can have a first trace 211 with a first exposed pad 225 and a second trace 213 with a second exposed pad 227. A wire bond 223 can run above the first conductive layer 201 to connect the first exposed pad 225 to the second exposed pad 227, such that the first trace 211 and the second trace 213 are only connected via the wire bond 223. The first trace 211 and the second trace 213 can be horizontally aligned on the first conductive layer 201. In alternative embodiments, the first trace 211 and the second trace 213 may occupy disparate heights, while being disposed on an equivalent conductive layer. Also included in the assembly 200 is a semiconductor device, which will be illustrated in later figures, the semiconductor device including an electrical connection to the first trace 211. Contrasted with FIG. 1B, the addition of a third trace 219 and a fourth trace 221 occupies only 245 μm, which is a much smaller space due to the replacement of the first via 115 and second via 117 with the first exposed pad 225 and the second exposed pad 227. In alternative embodiments, a gap can separate the first trace 211 from the second trace 213, the gap measuring up to 200 microns (e.g., in some embodiments 150 microns, in others 175 microns, etc.).

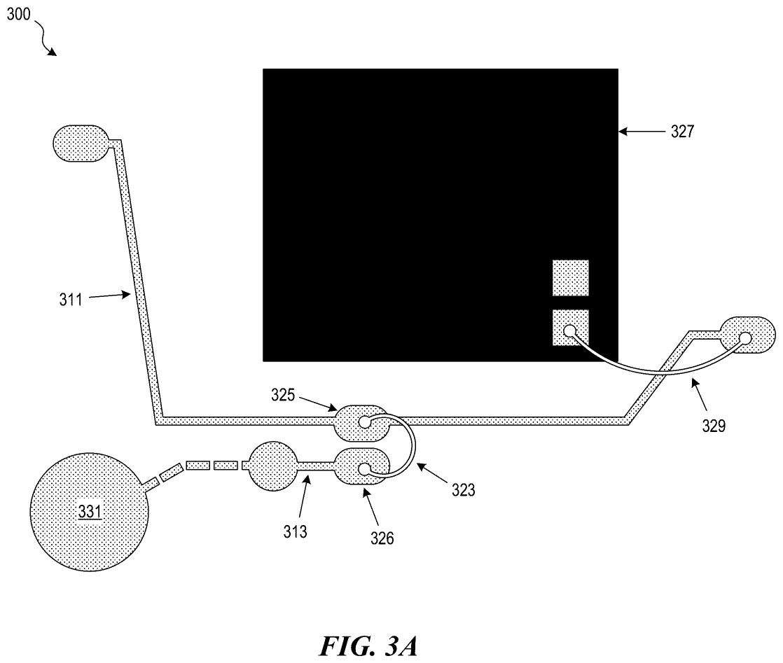

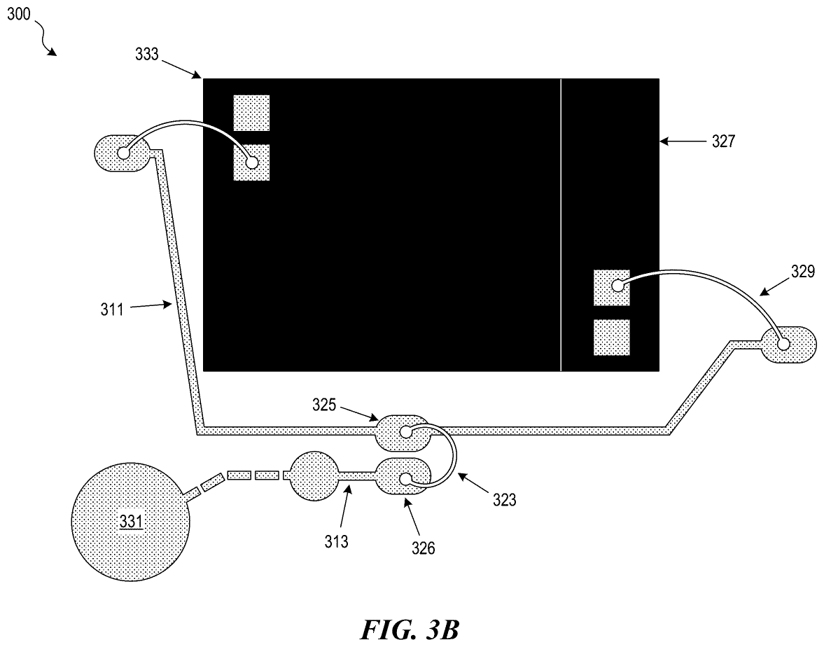

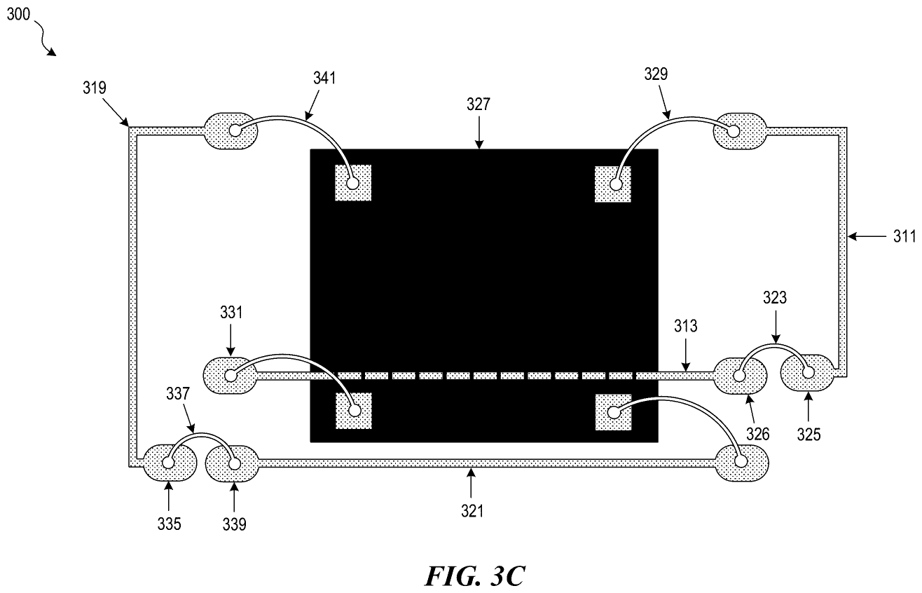

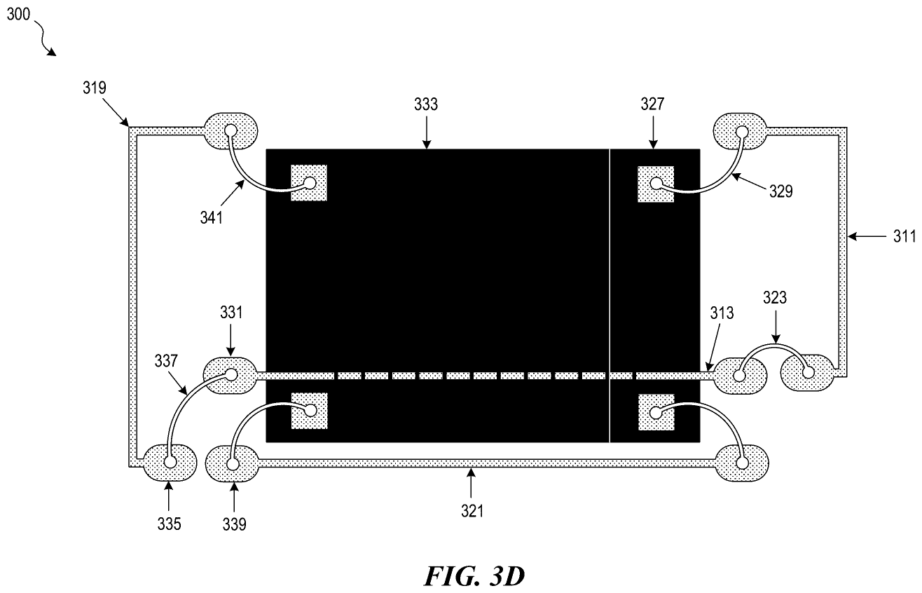

The flexibility and space-saving benefits afforded to the assembly 200 as a whole has particular implications for the semiconductor device as well. FIG. 3A is a simplified plan view of an example semiconductor assembly with wire-bonded traces. The assembly 300 can include a substrate, the substrate including a first conductive layer. The first conductive layer can have a first trace 311 with a first exposed pad 325 and a second trace 313 with a second exposed pad 326. A wire bond 323 can run above the first conductive layer to connect the first exposed pad 325 to the second exposed pad 326, such that the first trace 311 and the second trace 313 are only connected via the wire bond 323. The first trace 311 and the second trace 313 can be horizontally aligned on the first conductive layer. In alternative embodiments, the first trace 311 and the second trace 313 may occupy disparate heights, while being disposed on an equivalent conductive layer. Also included in the assembly 300 is a semiconductor device 327. The semiconductor device can include an electrical connection 329 to the first trace 311. The electrical connection 329 can be a wire bond, as illustrated, or it can be an external bump which has been surface-mounted and soldered to a plate belonging to the substrate. In other embodiments, the second trace 313 can have a third exposed pad 331. In such embodiments, the third exposed pad 331 can comprise a test pad for the semiconductor device 327, configured to be tested by a probe pin or by a solder ball. In additional embodiments, due to the flexibility granted to the assembly 300 by the wire-bonded traces, the semiconductor device 327 can be disposed a greater distance away from the second trace 313, and still be connected to it. The first trace 311 can have a first distance from the semiconductor device 327, the first distance measuring up to 3 mm, and the second trace 313 can have a second distance from the semiconductor device 327, the second distance measuring at least 3 mm. In other example assemblies, the second trace 313 can have a length that is shorter than a length of the first trace 311 for the very same reason.

The assembly 300 can further comprise a stack of semiconductor devices 333 disposed atop the semiconductor device 327, as illustrated in FIG. 3B. FIG. 3B is a simplified plan view of an example semiconductor assembly 300 with wire-bonded traces. The assembly 300 can include a substrate, the substrate including a first conductive layer. The first conductive layer can have a first trace 311 with a first exposed pad 325 and a second trace 313 with a second exposed pad 326. A wire bond 323 can run above the first conductive layer to connect the first exposed pad 325 to the second exposed pad 326, such that the first trace 311 and the second trace 313 are only connected via the wire bond 323. The first trace 311 and the second trace 313 can be horizontally aligned on the first conductive layer. In alternative embodiments, the first trace 311 and the second trace 313 may occupy disparate heights, while being disposed on an equivalent conductive layer. Also included in the assembly 300 is a semiconductor device 327. The semiconductor device can include an electrical connection 329 to the first trace 311. The electrical connection 329 can be a wire bond, as illustrated, or it can be an external bump which has been surface-mounted and soldered to a plate belonging to the substrate. Additionally, the stack of semiconductor devices 333 can have an electrical connection to the first trace 311. This connection can be a wire bond, as illustrated, or it can be an external bump which has been surface-mounted and soldered to a plate belonging to the substrate. In other embodiments, the second trace 313 can have a third exposed pad 331. In such embodiments, the third exposed pad 331 can comprise a test pad for the semiconductor device 327 and/or the stack of semiconductor devices 333, configured to be tested by a probe pin or by a solder ball. In additional embodiments, due to the flexibility granted to the assembly 300 by the wire-bonded traces, the semiconductor device 327 and the stack of semiconductor devices 333 can be disposed a greater distance away from the second trace 313, and still be connected to it. The first trace 311 can have a first distance from the semiconductor device 327, the first distance measuring up to 3 mm, and the second trace 313 can have a second distance from the semiconductor device 327 and the stack of semiconductor devices 333, the second distance measuring at least 3 mm. In other example assemblies, the second trace 313 can have a length that is shorter than a length of the first trace 311, the shorter length enabled by the wire-bond 323 connecting the second trace 313 to the first trace 311 and, by extension, to the semiconductor device 327 and the stack of semiconductor devices 333.

The assembly can further include a second wire bond. Additionally or alternatively, embodiments of the assembly can include a second electrical connection. FIG. 3C is a simplified plan view of an example semiconductor assembly 300 with wire-bonded traces. In the example assembly 300 from FIG. 3C, the wire bond can comprise a first wire bond 323, and the electrical connection can comprise a first electrical connection 329. The first conductive layer can further include a third trace 319 having a fourth exposed pad 335. A substrate belonging to the assembly 300 can further include a second wire bond 337 running above the first conductive layer to connect the fourth exposed pad 335 to a fifth exposed pad 339, the fifth exposed pad 339 belonging to a fourth trace 321. In some embodiments, the only electrical connection between the third trace 319 and the fourth trace 321 is by the second wire bond 337. The assembly 300 can include a second electrical connection 341. The second electrical connection 341 can be between the semiconductor device 327 and a trace, for example, the third trace 319, as illustrated.

Additionally or alternatively, the second wire bond 337 can connect the fourth exposed pad 335 to the third exposed pad 331, as illustrated in FIG. 3D. In such embodiments, the second wire bond 333 can connect the third trace 319 to the second trace 313. The assembly can further include a second semiconductor device, in which case the semiconductor device can include a first semiconductor device 327. The second semiconductor device can be disposed a distance away from the first semiconductor device 327. The second electrical connection 341 can connect the second semiconductor device to the third trace 319, such that the second semiconductor device is still electrically connected to the first semiconductor device 327 by way of the first wire bond 323 and the second wire bond 337. The assembly 300 can further comprises a stack of semiconductor devices 333 disposed atop the first semiconductor device 327, as illustrated in FIG. 3D.

FIG. 3D is a simplified plan view of an example semiconductor assembly 300 with wire-bonded traces. The second electrical connection 341 can be between the stack of semiconductor devices 333 and a trace, for example, the third trace 319, as illustrated. A width can encompass the first trace 311, the second trace 313, and the third trace 319, such that the width measures between 100 and 300 microns. This compact width—as compared to traces with vias—can be afforded to the assembly 300 due to the wire-bond connections between the traces.

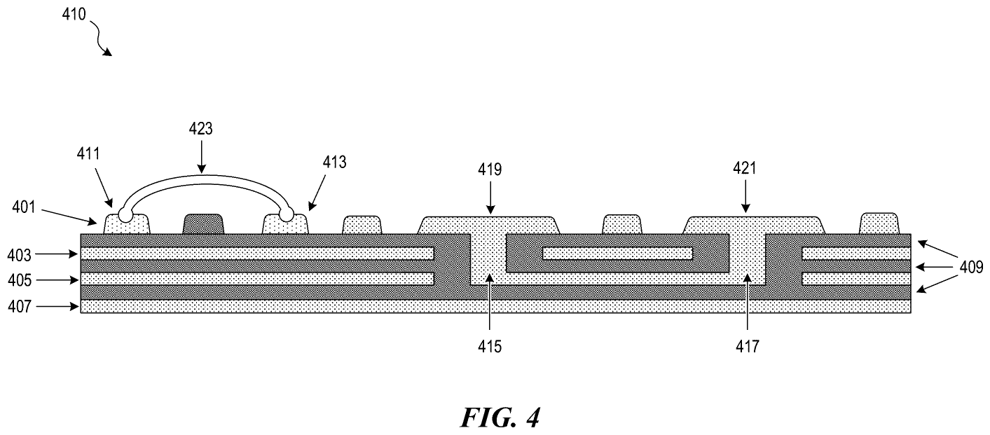

Separate from the foregoing descriptions and illustrations of semiconductor device assemblies, an isolated semiconductor substrate can additionally be considered as providing the same benefits described above, with regard to wire-bonding traces. FIG. 4 depicts a simplified cross-sectional view of an example substrate 410 with wire-bonded traces. The substrate 410 can include a first layer 401. The first layer can have a first conductive trace 411 with a first pad, a second conductive trace 413 with a second pad, and an interconnect wire 423 running over the first layer 401 to connect the first pad to the second pad. In some embodiments, the first conductive trace 411 and the second conductive trace 413 may only be electrically bonded to each other via the interconnect wire 423. In other embodiments, the substrate can further include a second layer 403 below the first layer 401, and an unbroken sheet of dielectric material 409 between the first layer 401 and the second layer 403. The second layer 403 can comprise an undivided conductive layer configured for routing power and for blocking electromagnetic crosstalk from reaching the first layer 401. As illustrated, the second layer 403 can be intersected by a first via 415 and a second via 417. The first layer 401 can further include a third conductive trace 419 with the first via 415, the third via connecting to a third layer 405 by running down through the second layer 403. The first layer 401 can further include a fourth conductive trace 421 with the second via 417, the second via 417 connecting to the third layer 405 by running down through the second layer 403. The third layer 405 can be configured to connect the third trace 419 to the fourth trace 421, such that dielectric material 409 separates the layers and surrounds the vias, preventing the vias from contacting the second layer 403, and breaking the second layer 403 into separate conductive segments.

Although in the foregoing example embodiment semiconductor device assemblies have been illustrated and described as including a single semiconductor device, in other embodiments assemblies can be provided with additional semiconductor devices. For example, the single semiconductor devices illustrated in FIGS. 3A and/or 3C could be replaced with, e.g., a vertical stack of semiconductor devices, a plurality of semiconductor devices, mutatis mutandis.

In accordance with one aspect of the present disclosure, the semiconductor devices illustrated in FIGS. 1A-3D could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

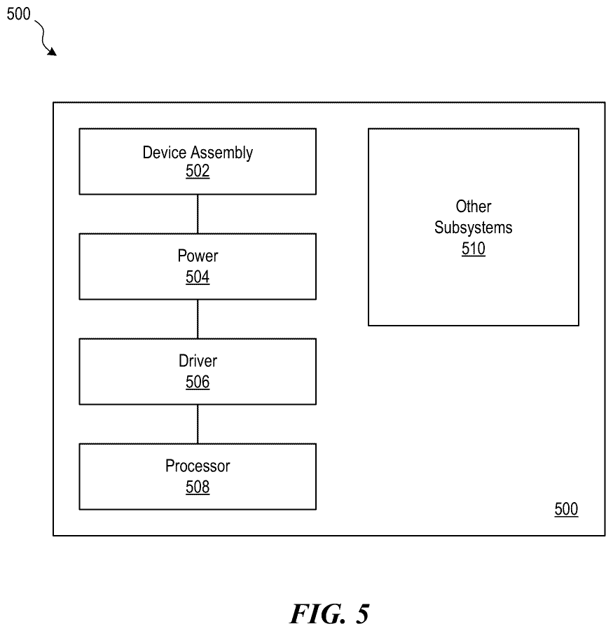

Any one of the semiconductor devices and semiconductor device assemblies described above with reference to FIGS. 1A-3D can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor device assemblies described above with reference to FIGS. 2A-3D. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer readable media.

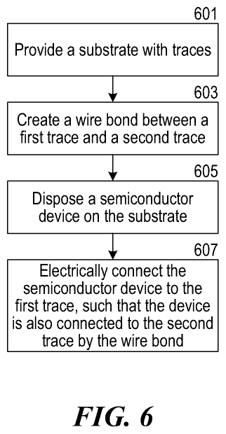

FIG. 6 is a flow chart illustrating a method of making a semiconductor device assembly. The method includes providing a substrate with a conductive layer, the conductive layer having a first trace with a first exposed pad and a second trace with a second exposed pad (box 601). The method further includes electrically connecting the first exposed pad to the second exposed pad by running a first wire bond over the first conductive layer, wherein the first trace and the second trace are only electrically connected to each other by the first wire bond (box 603). The method further includes disposing a semiconductor device on the substrate (box 605). In some methods, the semiconductor device can be disposed at least 3 mm away from the second trace at a closest distance. The method further includes electrically connecting the semiconductor device to the second trace by electrically connecting the device to the first trace, wherein the semiconductor device is electrically connected to the second trace by the first wire bond (box 607). The method can further include disposing a second semiconductor device on the substrate, wherein the semiconductor device is a first semiconductor device. The method can further include electrically connecting the second semiconductor device to a third trace with a third exposed pad. The method can further include electrically connecting the second semiconductor device to the first semiconductor device by running a second wire bond over the conductive layer to connect the third exposed pad to a fourth exposed pad belonging to the second trace, wherein the third trace and the second trace are only electrically connected to each other by the second wire bond. The fourth exposed pad can be a distance away from the second semiconductor device, such that the distance measures at least 3 mm, and a width encompasses all three traces, the width measuring between 100 and 300 μm.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate including:
a first conductive layer, the first conductive layer having:
a first trace with a first exposed pad,
a second trace with a second exposed pad, and
a wire bond extending above the first conductive layer and directly connecting the first exposed pad to the second exposed pad, wherein the first trace and the second trace are exclusive of any other electrical connection than the wire bond; and
a semiconductor device carried by the substrate, the semiconductor device being electrically coupled to the first trace.

2. The semiconductor device assembly of claim 1, wherein the first trace and the second trace are horizontally aligned on the first conductive layer.

3. The semiconductor device assembly of claim 1, wherein a gap separates the first trace from the second trace, the gap measuring between 5 and 100 microns.

4. The semiconductor device assembly of claim 1, wherein a dielectric layer covers the first conductive layer, the dielectric layer including first and second openings exposing the first exposed pad and the second exposed pad, respectively.

5. The semiconductor device assembly of claim 1, wherein the substrate further includes a second conductive layer below the first conductive layer, the second conductive layer including a continuous layer of conductive material configured to prevent electromagnetic crosstalk from reaching the first conductive layer.

6. The semiconductor device assembly of claim 1, wherein the second trace has a third exposed pad, the third exposed pad comprising a test pad for the semiconductor device outside a footprint of the semiconductor device.

7. The semiconductor device assembly of claim 6, wherein the first exposed pad is spaced further from the semiconductor device than the second exposed pad.

8. The semiconductor device assembly of claim 7, wherein the assembly further comprises a stack of semiconductor devices disposed atop the semiconductor device.

9. The semiconductor device assembly of claim 1, wherein the wire bond comprises a first wire bond, wherein the first conductive layer further includes a third trace having a fourth exposed pad, and wherein the substrate further includes:
a second wire bond extending above the first conductive layer to connect the fourth exposed pad to a third exposed pad of the second trace, wherein the third trace and the second trace are exclusive of any other electrical connection than the second wire bond.

10. The semiconductor device assembly of claim 9, wherein the assembly further comprises:
a second semiconductor device electrically coupled to the third trace, such that the second semiconductor device is electrically connected to the first semiconductor device by way of the first and second wire bonds.

11. A package substrate for carrying one or more semiconductor devices, the substrate comprising:
a metallization layer, the metallization layer having:
a first conductive trace with a first pad,
a second conductive trace with a second pad, and
an interconnect wire extending above the metallization layer to connect the first pad to the second pad, wherein the first conductive trace and the second conductive trace are exclusive of any other electrical connection than the wire bond.

12. The package substrate of claim 11, wherein a gap separates the first conductive trace from the second conductive trace, the gap measuring between 5 and 100 microns.

13. The package substrate of claim 11, wherein a dielectric layer covers the metallization layer, the dielectric layer including first and second openings exposing the first pad and the second pad, respectively.

14. The package substrate of claim 11, further comprising a ground plane layer below the metallization layer, the ground plane layer including a continuous layer of conductive material configured to prevent electromagnetic crosstalk from reaching the metallization layer.

15. The package substrate of claim 11, wherein the metallization layer further includes:
a third conductive trace with a first via, the first via extending through a second layer of the package substrate to a third layer of the package substrate, and
a fourth conductive trace with a second via, the second via extending through the second layer to the third layer, wherein the third layer is configured to electrically connect the third trace to the fourth trace.

16. A method of making a semiconductor device assembly, the method comprising:
providing a substrate with a metallization layer, the metallization layer having a first trace with a first exposed pad and a second trace with a second exposed pad; and
electrically connecting the first exposed pad to the second exposed pad with a first wire bond that extends over the first conductive layer, wherein the first trace and the second trace are only electrically connected to each other by the first wire bond.

17. The method of claim 16, wherein the method further comprises:
disposing a semiconductor device on the substrate; and
electrically coupling the semiconductor device to the second trace by directly connecting the device to the first trace, wherein the semiconductor device is electrically coupled to the second trace by the first wire bond.

18. The method of claim 17, wherein the semiconductor device is a first semiconductor device, and wherein the method further comprises:
disposing a second semiconductor device on the substrate;
electrically connecting the second semiconductor device to a third trace of the metallization layer at a third exposed pad;
electrically connecting the second semiconductor device to the first semiconductor device with a second wire bond extending over the conductive layer to connect the third exposed pad to a fourth exposed pad belonging to the second trace, wherein the third trace and the second trace are only electrically connected to each other by the second wire bond.

19. The method of claim 16, wherein a gap separates the first trace from the second trace, the gap measuring between 5 and 100 microns.
